(19) United States
(12) Patent Application Publication
(10) Pub. No.: US 2025/0115184 A1
(43) Pub. Date: Apr. 10, 2025

(54) VEHICULAR INTERIOR MIRROR ASSEMBLY WITH ENHANCED COOLING

(71) Applicant: Magna Mirrors of America, Inc., Holland, MI (US)

(72) Inventors: Anthony J. LaCross, Hastings, MI (US); Austen C. Peterson, Hudsonville, MI (US)

(21) Appl. No.: 18/905,263

(22) Filed: Oct. 3, 2024

Related U.S. Application Data
(60) Provisional application No. 63/588,352, filed on Oct. 6, 2023.

(51) Int. Cl. B60R 1/12; B60R 1/04

(52) U.S. Cl. CPC B60R 1/12; B60R 1/04; B60R 2001/1253

(57) ABSTRACT

A vehicular interior rearview mirror assembly includes a mirror head adjustable about a mounting structure that includes an arm having a ball member. The mirror head includes a socket that receives the ball member. The arm and the ball member have a passageway. The mirror head accommodates an electronic component and a heatsink that is thermally coupled to the electronic component and draws heat away from the electronic component when the electronic component is electrically operated and generates heat within the interior cavity of the mirror head. An air source directs airflow through the passageway and into the interior cavity of the mirror head and the airflow flows through the interior cavity of the mirror head and exits the interior cavity of the mirror head to dissipate heat from the heatsink and the interior cavity of the mirror head.

### CROSS REFERENCE TO RELATED APPLICATION

The present application claims the filing benefits of U.S. provisional application Ser. No. 63/588,352, filed Oct. 6, 2023, which is hereby incorporated herein by reference in its entirety.

### FIELD OF THE INVENTION

The present invention relates generally to the field of interior rearview mirror assemblies for vehicles.

### BACKGROUND OF THE INVENTION

It is known to provide a mirror assembly that is adjustably mounted to an interior portion of a vehicle, such as via a single or double ball pivot or joint mounting configuration where the mirror casing and reflective element are adjusted relative to the interior portion of a vehicle by pivotal movement about the single or double ball pivot configuration. The mirror casing and reflective element are pivotable about either or both of the ball pivot joints by a user that is adjusting his or her rearward view.

### SUMMARY OF THE INVENTION

A vehicular interior rearview mirror assembly includes a mirror head adjustable relative to a mounting assembly. The mounting assembly includes a base portion configured to attach at an interior portion of a vehicle, and an arm having a ball member. The mirror head includes a mirror casing and a mirror reflective element. The mirror casing includes a socket that receives a ball member to adjustably mount the mirror head to the mounting assembly. A passageway extends along the arm and the ball member. The passageway is in fluid communication with an interior portion of the mirror head, such as via an opening formed through the mirror casing at the socket. The mirror head accommodates an electronic component that generates heat within the interior portion of the mirror head when the electronic component is electrically operated. The mirror head accommodates a heat sink that is thermally coupled to the electronic component. When the electronic component generates heat within the mirror head, the heat sink draws heat away from the electronic component. With the base portion attached at the interior portion of the vehicle, an air source directs airflow along the passageway of the arm and into the interior portion of the mirror head. The airflow flows along the heat sink and exits the mirror head to dissipate heat from the heat sink and the interior portion of the mirror head.

These and other objects, advantages, purposes and features of the present invention will become apparent upon review of the following specification in conjunction with the drawings.

### BRIEF DESCRIPTION OF THE DRAWINGS

FIG. 1 is a perspective view of a vehicular interior rearview mirror assembly;

FIGS. 2 and 3 are perspective views of the mirror assembly, with the mirror casing removed to show a heatsink accommodated by the mirror head and a fan assembly attached to the mounting arm;

FIG. 4 is a sectional view of the heatsink, mounting arm and fan assembly;

FIG. 5 is a perspective view of the fan assembly; and

FIGS. 6-8 are views of the fan assembly attached to the mounting arm.

### DESCRIPTION OF THE PREFERRED EMBODIMENTS

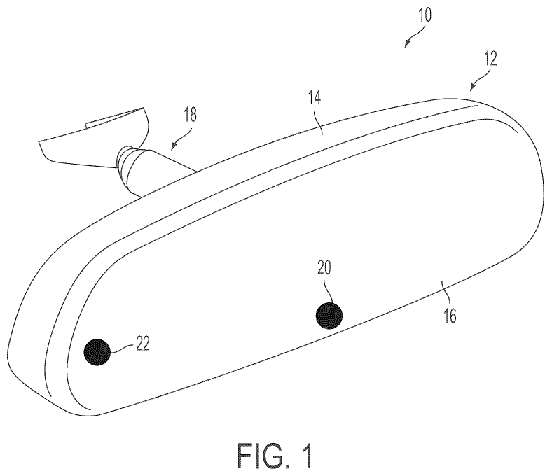

Referring now to the drawings and the illustrative embodiments depicted therein, an interior rearview mirror assembly 10 for a vehicle includes a mirror head 12 that includes a casing 14 and a reflective element 16 positioned at a front portion of the casing 14 (FIG. 1). In the illustrated embodiment, the mirror assembly 10 is configured to be adjustably mounted to an interior portion of a vehicle (such as to an interior or in-cabin surface of a vehicle windshield or a headliner of a vehicle or the like) via a mounting structure or mounting configuration or assembly 18. The mirror reflective element may comprise a variable reflectance mirror reflective element, such as an electrochromic mirror reflective element, that varies its reflectance responsive to electrical current applied to conductive coatings or layers of the reflective element.

The interior rearview mirror assembly 10 accommodates one or more heat generating electronic components within the mirror head 12. For example, a printed circuit board (PCB) having one or more heat generating electronic components (e.g., one or more image or data processors, one or more light emitters, one or more cameras and the like) and/or a video display screen may be accommodated by the mirror casing 14 behind the mirror reflective element 16. When the electronic components (including the display screen) are electrically operated, heat is generated at the interior cavity or interior portion of the mirror head 12 and can, if operated without sufficient cooling, exceed the functional thermal load of the components. Thus, and as described further below, the mirror assembly 10 is configured to provide enhanced cooling for the heat generating electronic components accommodated by the mirror head by dissipating heat away from the electronic components and out of the interior cavity of the mirror head.

The mirror assembly may comprise an auto-dimming mirror reflective element (e.g., an electrochromic mirror reflective element) or a prismatic mirror reflective element. Both types of mirrors may be provided with a video display screen that is disposed behind and is viewable through the mirror reflective element. Such video mirrors include a backlit LCD display screen, and a particular form of video mirror is a full display mirror (such as a ClearView™ Interior Rearview Mirror Assembly available from Magna Mirrors of America, Inc. of Holland, MI USA, or an FDM™ Interior Rearview Mirror Assembly available from Gentex Corporation of Zeeland, MI USA), where the video display screen fills the reflective region, such as by utilizing aspects of the mirror assemblies and systems described in U.S. Pat. Nos. 11,242,008; 11,214,199; 10,442,360; 10,421,404; 10,166,924; 10,046,706 and/or 10,029,614, and/or U.S. Publication Nos. US-2021-0162926; US-2019-0258131; US-2019-0146297; US-2019-0118717 and/or US-2017-0355312, which are all hereby incorporated herein by reference in their entireties. When electrically operated to display images through the mirror reflective element 16, the video display screen generates heat within the mirror head 12.

Further, the mirror assembly 10 may include or be associated with a driver monitoring system (DMS) and/or an occupant monitoring system (OMS), with the mirror assembly including a driver/occupant monitoring camera 20 disposed at a back plate (and viewing through an aperture of the back plate) behind the reflective element 16 and viewing through the reflective element 16 toward at least a head region of the driver of the vehicle. The DMS may include an infrared light (IR light) or near infrared light (near IR light) emitter 22 disposed at the back plate and emitting IR light or near IR light that passes through another aperture of the back plate and through the reflective element 16. Further, the monitoring system includes an electronic control unit (ECU) having electronic circuitry and associated software, including an image processor for processing image data captured by the DMS/OMS camera. Image data captured by the camera may be processed for a head and face direction and position tracking system and/or eye tracking system and/or gesture recognition system. The DMS camera and monitoring system and/or head and face direction and/or position tracking systems and/or eye tracking systems and/or gesture recognition systems may utilize aspects of the systems described in U.S. Pat. Nos. 11,827,153; 11,780,372; 11,639,134; 11,582,425; 11,518,401; 10,958,830; 10,065,574; 10,017,114; 9,405,120 and/or 7,914,187, and/or U.S. Publication Nos. US-2024-0190456; US-2024-0168355; US-2022-0377219; US-2022-0254132; US-2022-0242438; US-2021-0323473; US-2021-0291739; US-2020-0320320; US-2020-0202151; US-2020-0143560; US-2019-0210615; US-2018-0231976; US-2018-0222414; US-2017-0274906; US-2017-0217367; US-2016-0209647; US-2016-0137126; US-2015-0352953; US-2015-0296135; US-2015-0294169; US-2015-0232030; US-2015-0092042; US-2015-0022664; US-2015-0015710; US-2015-0009010 and/or US-2014-0336876, and/or U.S. patent application Ser. No. 18/666,959, filed May 17, 2024 (Attorney Docket DON01 P5121), and/or U.S. provisional application Ser. No. 63/641,574, filed May 2, 2024, and/or International Publication No. WO 2023/220222, which are all hereby incorporated herein by reference in their entireties.

Optionally, the driver monitoring system may be integrated with a camera monitoring system (CMS) of the vehicle. The integrated vehicle system incorporates multiple inputs, such as from the inward viewing or driver monitoring camera and from a forward or outward viewing camera, as well as from a rearward viewing camera and sideward viewing cameras of the CMS, to provide the driver with unique collision mitigation capabilities based on full vehicle environment and driver awareness state. The image processing and detections and determinations are performed locally within the interior rearview mirror assembly and/or the overhead console region, depending on available space and electrical connections for the particular vehicle application. The CMS cameras and system may utilize aspects of the systems described in U.S. Pat. No. 11,242,008 and/or U.S. Publication Nos. US-2024-0064274; US-2021-0245662; US-2021-0162926; US-2021-0155167; US-2018-0134217 and/or US-2014-0285666, which are all hereby incorporated herein by reference in their entireties.

The ECU may receive image data captured by a plurality of cameras of the vehicle, such as by a plurality of surround view system (SVS) cameras and a plurality of camera monitoring system (CMS) cameras and optionally one or more driver monitoring system (DMS) cameras. The ECU may comprise a central or single ECU that processes image data captured by the cameras for a plurality of driving assist functions and may provide display of different video images to a video display screen in the vehicle (such as at the interior rearview mirror assembly or at a central console or the like) for viewing by a driver of the vehicle. The system may utilize aspects of the systems described in U.S. Pat. No. 11,242,008; 10,442,360 and/or 10,046,706, and/or U.S. Publication Nos. US-2024-0064274; US-2021-0245662; US-2021-0162926; US-2021-0155167 and/or US-2019-0118717, which are all hereby incorporated herein by reference in their entireties.

Electronic components associated with the DMS and/or the CMS generate heat at the interior of the mirror head 12. For example, the near IR light emitter 22, when electrically operated to emit light through the mirror reflective element 16, generates heat. Further, the ECU disposed within the mirror head includes one or more data processors or image processors for processing image data and/or sensor data for the DMS, OMS, and/or CMS functions. When the one or more processors are operated to process the sensor data, heat is generated within the mirror head 12.

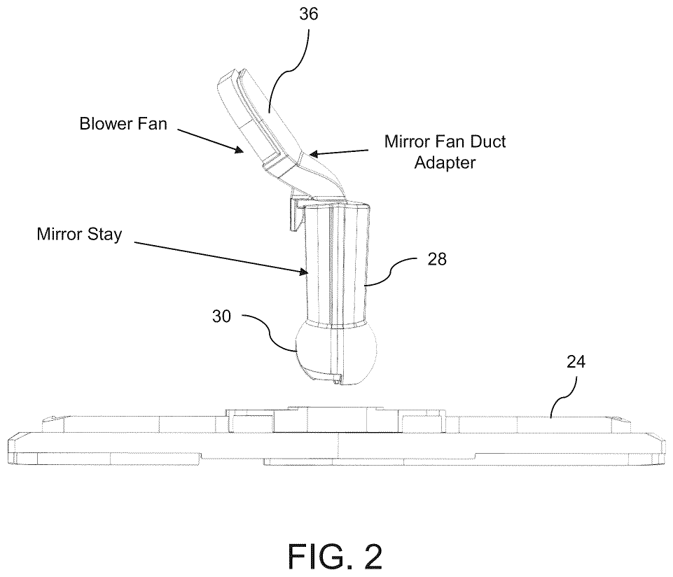

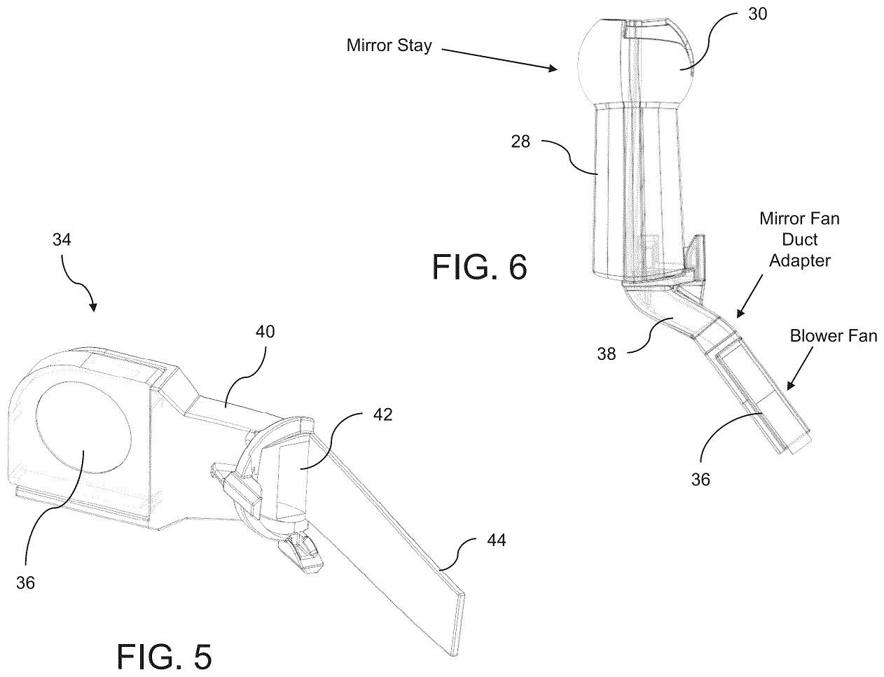

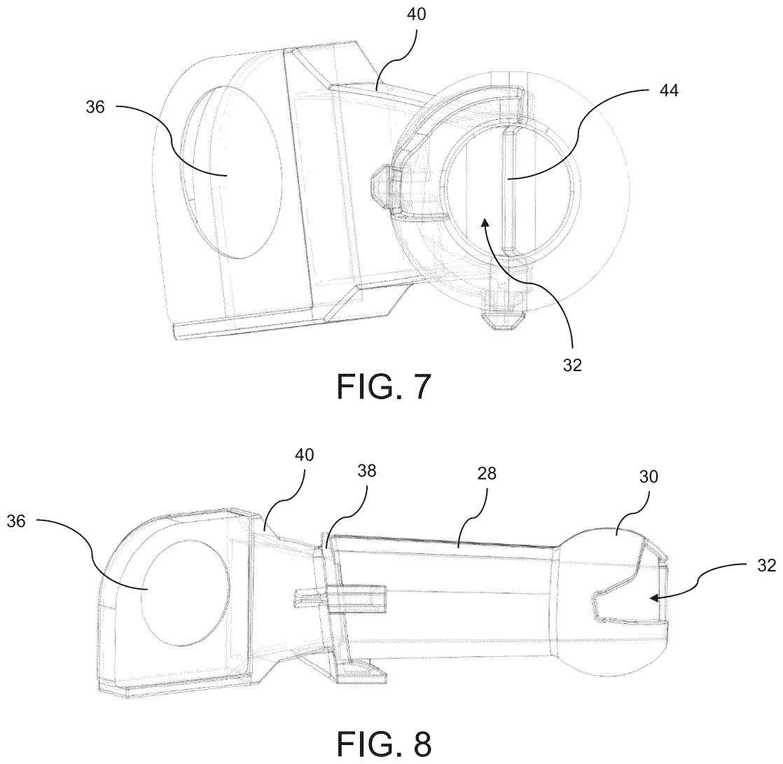

Referring to FIGS. 2-8, one or more heatsinks or heat dissipating elements 24 may be thermally coupled to the heat generating electronic components to draw heat away from the components, where the heat may be dissipated from the heatsink 24 and exterior of the mirror head 12, such as to the ambient air of the cabin through the exterior surface of the mirror casing 14 and/or via one or more vents or slots formed through the mirror casing 14 that allow cooling airflow to pass through the interior portion of the mirror head and draw heat away from the heatsink. For example, the heatsink and mirror head may utilize characteristics of the mirror assemblies described in U.S. patent application Ser. No. 18/739,528, filed Jun. 11, 2024 (Attorney Docket DON01 P5141), which is hereby incorporated herein by reference in its entirety.

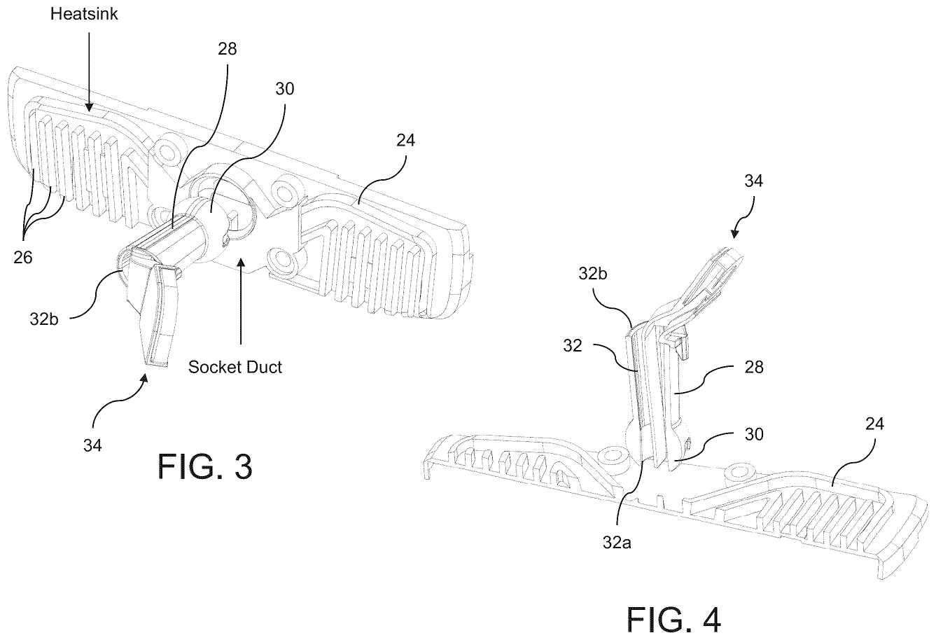

In the illustrated example of FIGS. 3 and 4, the heatsink 24 includes a plurality of heat dissipating fins 26 thermally coupled to the heat generating electronic components. The heatsink 24 may include or attach to a mirror back plate, with the mirror reflective element 16 adhesively attached at the mirror back plate with the PCB and/or video display screen disposed between the mirror back plate (or heatsink) and the mirror reflective element 16. A thermally conductive adhesive may attach the PCB, the mirror back plate and/or the heatsink 24 to one another to promote thermal transfer from the electronic component to the heatsink 24. Thus, when the one or more heat generating electronic components are electrically operated, heat generated by the heat generating components is dissipated through the mirror back plate and/or the heatsink 24 and heat dissipating fins 26 to the mirror casing 14 and/or air within the mirror head between the mirror casing 14 and the heatsink 24.

The mounting structure 18 of the mirror assembly 10 includes a mirror stay or mounting arm 28 that has a ball member 30 at a first end of the mounting arm 28. The mirror casing 14 includes a socket that receives the ball member 30 to form a pivot joint between the mirror head 12 and the mounting arm 28. For example, the socket may be integrally formed with the mirror backplate, the mirror casing and/or the heatsink 24 (FIG. 3). The second end of the mounting arm 28 opposite the ball member 30 is configured to attach at the interior portion of the vehicle cabin, such as via a mounting button or other mounting structure.

An inner passageway or channel 32 extends along the mounting arm 28 between a first opening 32a at the ball member 30 and a second opening 32b at the end of the mounting arm 28 opposite the ball member 30. Electrical wiring or connectors may extend along the passageway 32 and through an opening or aperture at the socket of the mirror casing 14 to electrically connect the mirror assembly 10 to a vehicular wire harness.

An air source may be configured to direct cooling airflow along the passageway 32 of the mounting arm 28 and into the mirror head 12, so that the airflow moves along and between the heat dissipating fins 26 and out of the mirror head 12, such as through vents or slots formed in the mirror casing 14. For example, vents or slots may be formed through the mirror casing at or near respective ends of the heat dissipating fins 26, such as along an upper region of the mirror casing and along a lower region of the mirror casing and/or along opposing side regions of the mirror casing. Thus, the cooling airflow may flow from the first opening 32a at the ball member 30 and along channels formed between adjacent heat dissipating fins 26 and out of the interior cavity of the mirror head through respective vents or slots. In the illustrated example, the heat dissipating fins 26 form channels that direct air from the central portion of the mirror head at or near the socket, along an upper edge region of the mirror head and down toward vents or slots at a lower edge region of the mirror head. The heat dissipating fins 26 may define channels in any suitable pattern or configuration within the mirror head, such as extending radially outward from the central portion to the perimeter region of the mirror head, horizontally between opposing sides of the mirror head, vertically between the upper and lower edge regions of the mirror head, and the like. Thus, the interior portion of the mirror casing 14 is in fluid communication with the passageway 32 of the mounting arm 28 via the hole or aperture at the socket of the mirror casing 14, and active airflow is directed through the passageway 32 and into the mirror head 12 to dissipate heat from the heatsink 24 and heat dissipating fins 26.

An airflow source directs the active airflow toward the passageway 32 and into the mirror head 12. For example, the passageway 32 may be in fluid communication with a heating, ventilation and air conditioning (HVAC) system of the vehicle for receiving cooling airflow from a blower of the HVAC system. Optionally, the airflow source may be disposed at or near the mirror assembly. In the illustrated example of FIGS. 2-8, a fan assembly 34 is attached to or integrally formed with the mounting arm 28 and is electrically operable to direct the cooling airflow along the passageway 32 toward the mirror head 12. The fan assembly 34 includes a blower fan 36, such as a radial fan that directs air in a radial direction perpendicular to an axis of rotation of the fan 36, and that is electrically operable to generate the airflow. An adapter or attaching portion 38 of the fan assembly 34 attaches to the second end of the mounting arm 28, such as via flexible tabs or snaps that engage corresponding structure at the mounting arm 28 to secure the fan assembly 34 at the mounting arm 28. The attaching portion 38 includes an air conduit or channel 40 that, with the attaching portion 38 secured at the mounting arm 28, extends between the fan 36 and the mounting arm 28 and includes a passageway 42 that carries the airflow from the fan toward the passageway 32 of the mounting arm 28. The attaching portion 38 may extend at an angle (e.g., an oblique angle) relative to a longitudinal axis of the mounting arm 28 so that the fan assembly 34 may be hidden behind a surface of the vehicle (e.g., the headliner or a vent cover disposed at the headliner).

A guide or planar arm or tab 44 extends from the attaching portion 38 so that, with the fan assembly 34 attached at the mounting arm 28, the guide 44 extends at least partially along the passageway 32 of the mounting arm 28 toward the mirror head 12. The guide 44 is configured to provide a barrier between the electrical connectors or wires extending along the passageway 32 and the airflow directed along the passageway 32. Thus, the guide 44 provides a smooth surface for the airflow to travel along to limit air speed reduction along the passageway 32 and to reduce or prevent air noise.

When the mounting arm 28 is attached at the interior portion of the vehicle, the fan 36 is in fluid communication with cool ambient air. For example, the air conduit 40 may extend from the mounting arm 28 and at least partially along a headliner of the vehicle so that the fan 36, or at least an air conduit in communication with the fan 36, is exposed to air within the interior cabin of the vehicle (e.g., through the vent cover at the headliner). Optionally, the fan 36 extends from the mounting arm 28 and within the headliner of the vehicle where the fan 36 is in fluid communication with cooled air from the HVAC system of the vehicle.

Thus, when electrically operated to provide cooling to the mirror head, the fan 36 directs cooling airflow along the passageway 42 of the air conduit 40 and toward the passageway 32 of the mounting arm 28. The cooling airflow enters the mirror head 12 at the ball socket joint through the opening 32a at the ball member 30. The cooling airflow may pressurize or slightly pressurize the mirror head 12 and travel between and along the heat dissipating fins 26 of the heatsink 24 before exiting the mirror head 12, such as via vents or slots formed in the mirror casing 14. The cooling airflow draws heat away from the heat dissipating fins 26 and out of the mirror head 12, thus providing enhanced cooling to the mirror assembly 10.

In other words, mirrors with thermal constraints can be cooled by using a stay that integrates a duct adapter and fan. The duct adapter and fan package outside of the mirror head as a part of the stay by clipping onto the stay neck. The duct adapter provides a mechanical structure for the fan to mount to, while also carefully controlling and maintaining the surface area that the air travels through to limit inefficiencies related to air speed reduction and noise. In the illustrated embodiment, the air is pulled through the blower fan (from the cool cabin air volume) and is pushed through the duct and into the mirror head. Once the air is in the mirror head, it travels through the mirror socket/socket duct to pressurize the mirror head. Because air tends to follow the path of least resistance, the airflow will travel along and between the fins on the heatsink and out of the mirror head via vents or slots in the mirror casing.

In some examples, the mounting structure 18 is in thermally conductive communication with the heatsink 24 and the interior of the mirror casing 14. For example, the socket at the mirror head 12 may be integrally formed with the heatsink 24, or at least thermally coupled to the heatsink 24, such as via thermal paste and/or bosses attaching the heatsink 24 and the mirror casing 14 and/or socket. The socket and ball member 30 and mounting arm 28 may be formed from a thermally conductive material, such as a thermally conductive plastic or metallic material, with the ball member 30 engaging the socket and thus drawing heat dissipated to the socket. Thus, heat dissipated to the heatsink 24 may be dissipated through the socket to the ball member 30 and the mounting arm 28, where the mounting arm 28 and ball member 30 may be cooled by ambient air within the vehicle cabin.

Thermally coupling the socket and the ball member 30 and mounting arm 28 may provide improved cooling to the mirror head 12 and reduce or eliminate thermal expansion of the socket relative to the ball member 30. For example, when heat generated at the interior of the mirror head causes thermal expansion of the socket relative to the ball member 30, the compression force from the socket on the ball member 30 may be reduced and the mirror head 12 may fall or tilt or droop relative to the mounting structure. Optionally, a biasing member, such as a coil spring circumscribing the socket, may urge the socket into engagement with the ball member 30.

In other words, mirrors with thermal constraints can be cooled by using a thermally conductive socket (to pull heat from the heatsink to the mirror stay) and damping system (to counteract decreased socket torque from increased/changing temperatures that may cause mirror head droop). The mirror socket is constructed of thermally conductive plastic and is both mechanically and thermally bonded to the heatsink via bosses and thermal paste. The mirror socket is aided by a spring that counteracts the mirror head droop. That is, a torsion, compression, or extension spring counters the force of gravity on the mirror and provides force in a direction that pulls up on the mirror head relative to the vehicle. Further, the torsion, compression, or extension spring may increase the friction force on the ball and socket joint of the stay to increase the adjustment force and add resistance to the accidental movement of the mirror.

Thus, interior rearview mirrors may be equipped with electronic components associated with advanced features, such as the DMS, a digital display mirror with a video display screen, and the like. When these features are operated, a significant amount of heat may be generated and trapped inside the plastic housing of the mirror head. The mirror stay with integrated fan draws cool air from the environment and forces or guides or pushes it into the environment. Further, the thermally conductive socket and damper promotes additional avenues for heat to transfer through the mirror pivot socket. Thus, the mirror assembly facilitates improved thermal transfer from the mirror to the environment.

The interior mirror assembly may comprise a dual-mode interior rearview video mirror that can switch from a traditional reflection mode to a live-video display mode, such as is by utilizing aspects of the mirror assemblies and systems described in U.S. Pat. Nos. 11,242,008; 11,214,199; 10,442,360; 10,421,404; 10,166,924; 10,046,706 and/or 10,029,614, and/or U.S. Publication Nos. US-2024-0064274; US-2021-0162926; US-2021-0155167; US-2020-0377022; US-2019-0258131; US-2019-0146297; US-2019-0118717 and/or US-2017-0355312, which are all hereby incorporated herein by reference in their entireties. The video display screen of the video mirror, when the mirror is in the display mode, may display video images derived from video image data captured by a rearward viewing camera, such as a rearward camera disposed at a center high-mounted stop lamp (CHMSL) location, and/or video image data captured by one or more other cameras at the vehicle, such as side-mounted rearward viewing cameras or the like, such as by utilizing aspects of the display systems described in U.S. Pat. No. 11,242,008, which is hereby incorporated herein by reference in its entirety. The operating mode of the mirror and video display screen may be selected by flipping the mirror head upward or downward (e.g., via a toggle located at the mirror head) or responsive to another user input. When the mirror is operating in the mirror mode, the video display screen is deactivated and rendered covert by the mirror reflective element, and the driver views rearward via reflection of light incident at the mirror reflective element. When the mirror is operating in the display mode, the video display screen is operated to display video images that are viewable through the mirror reflective element by the driver of the vehicle.

The mirror assembly may comprise any suitable construction, such as, for example, a mirror assembly with the reflective element being nested in the mirror casing and with a bezel portion that circumscribes a perimeter region of the front surface of the reflective element, or with the mirror casing having a curved or beveled outermost exposed perimeter edge around the reflective element and with no overlap onto the front surface of the reflective element (such as by utilizing aspects of the mirror assemblies described in U.S. Pat. Nos. 7, 184, 190; 7,274,501; 7,255,451; 7,289,037; 7,360,932; 7,626,749; 8,049,640; 8,277,059 and/or 8,529,108, which are hereby incorporated herein by reference in their entireties) or such as a mirror assembly having a rear substrate of an electro-optic or electrochromic reflective element nested in the mirror casing, and with the front substrate having a curved or beveled outermost exposed perimeter edge, or such as a mirror assembly having a prismatic reflective element that is disposed at an outer perimeter edge of the mirror casing and with the prismatic substrate having a curved or beveled outermost exposed perimeter edge, such as described in U.S. Pat. Nos. 9,827,913; 9,174,578; 8,508,831; 8,730,553; 9,598,016 and/or 9,346,403, and/or U.S. Des. Pat. Nos. D633,423; D633,019; D638,761 and/or D647,017, which are hereby incorporated herein by reference in their entireties (and with electrochromic and prismatic mirrors of such construction are commercially available from the assignee of this application under the trade name INFINITY™ mirror).

Although shown as an electrochromic mirror application, it is envisioned that the mirror assembly may comprise a prismatic reflective element. The prismatic mirror assembly may be mounted or attached at an interior portion of a vehicle (such as at an interior surface of a vehicle windshield) via the mounting means described above, and the reflective element may be toggled or flipped or adjusted between its daytime reflectivity position and its nighttime reflectivity position via any suitable toggle means, such as by utilizing aspects of the mirror assemblies described in U.S. Pat. Nos. 6,318,870 and/or 7,249,860, and/or U.S. Publication No. US-2010-0085653, which are hereby incorporated herein by reference in their entireties. Optionally, for example, the interior rearview mirror assembly may comprise a prismatic mirror assembly, such as the types described in U.S. Pat. Nos. 7,289,037; 7,249,860; 6,318,870; 6,598,980; 5,327,288; 4,948,242; 4,826,289; 4,436,371 and/or 4,435,042, which are hereby incorporated herein by reference in their entireties. Optionally, the prismatic reflective element may comprise a conventional prismatic reflective element or prism or may comprise a prismatic reflective element of the types described in U.S. Pat. Nos. 7,420,756; 7,289,037; 7,274,501; 7,249,860; 7,338,177 and/or 7,255,451, which are all hereby incorporated herein by reference in their entireties.

The mirror back plate may comprise any suitable construction. Optionally, for example, a common or universal backplate, whereby the appropriate or selected socket element or pivot element (such as a socket element or such as a ball element or the like) is attached to the backplate to provide the desired pivot joint for the particular mirror head in which the backplate is incorporated. Optionally, when molding the backplate, a different insert may be provided to integrally mold a portion of or all of a ball member or the like (such as a portion of a base of a ball member, whereby the ball member may comprise a metallic ball member that is insert molded at the base and at the rear of the backplate during the injection molding process that forms the backplate, such as by utilizing aspects of the mirror assemblies described in U.S. Pat. Nos. 7,855,755; 7,249,860 and 6,329,925 and/or U.S. Pat. Pub. No. US-2006-0061008, which are hereby incorporated herein by reference in their entireties).

The mounting base includes an attaching portion that is configured to be attached to an interior surface of a vehicle windshield (such as to a mounting button or attachment element adhered to the interior surface of the vehicle windshield or such as to a headliner or overhead console of the vehicle). The mounting base may comprise a metallic ball portion or may comprise a molded (such as injection molded) polymeric mounting base or may be otherwise formed, depending on the particular application of the mirror assembly.

Changes and modifications in the specifically described embodiments may be carried out without departing from the principles of the present invention, which is intended to be limited only by the scope of the appended claims as interpreted according to the principles of patent law.

1. A vehicular interior rearview mirror assembly, the vehicular interior rearview mirror assembly comprising:
a mirror head adjustable about a mounting structure, wherein the mounting structure is configured to mount the vehicular interior rearview mirror assembly at an interior portion of an interior cabin of a vehicle;
wherein the mounting structure includes an arm having a ball member;
wherein the mirror head comprises a mirror reflective element and a socket, and wherein the socket receives the ball member to adjustably mount the mirror head at the mounting structure;
wherein the arm and the ball member have a passageway;
an electronic component accommodated within an interior cavity of the mirror head;
a heatsink accommodated by the mirror head, wherein the heatsink is thermally coupled to the electronic component;
wherein, when the electronic component is electrically operated and generates heat within the interior cavity of the mirror head, the heatsink draws heat away from the electronic component; and
wherein, with the vehicular interior rearview mirror assembly mounted at the interior portion of the interior cabin of the vehicle, an air source directs airflow through the passageway of the arm and the ball member and into the interior cavity of the mirror head, and wherein the airflow flows through the interior cavity of the mirror head and exits the interior cavity of the mirror head to dissipate heat from the heatsink and the interior cavity of the mirror head.

2. The vehicular interior rearview mirror assembly of claim 1, wherein the ball member is disposed at a first end of the arm, and wherein the passageway has a first opening at the ball member and a second opening at a second end of the arm opposite the first end.

3. The vehicular interior rearview mirror assembly of claim 2, wherein the air source comprises a fan assembly disposed at the second end of the arm, and wherein the fan assembly comprises an electrically operable fan that, when electrically operated, directs the airflow toward the second opening of the passageway.

4. The vehicular interior rearview mirror assembly of claim 3, wherein the fan assembly comprises an attaching portion that attaches at the second end of the arm and that extends between the electrically operable fan and the second end of the arm, and wherein an air conduit extends along the attaching portion so that the electrically operable fan, when electrically operated, directs the airflow through the air conduit toward the second opening of the passageway.

5. The vehicular interior rearview mirror assembly of claim 4, wherein the fan assembly comprises a guide portion that extends from the attaching portion and at least partially along the passageway.

6. The vehicular interior rearview mirror assembly of claim 3, wherein the electrically operable fan comprises a radial fan that directs air in a radial direction relative to an axis of rotation of the electrically operable fan.

7. The vehicular interior rearview mirror assembly of claim 1, wherein the mirror head comprises one or more vents formed through an outer surface of the mirror head, and wherein the airflow exits the interior cavity of the mirror head through the one or more vents.

8. The vehicular interior rearview mirror assembly of claim 1, wherein, with the vehicular interior rearview mirror assembly mounted at the interior portion of the interior cabin of the vehicle, an electrical connector passes through the passageway to electrically connect the electronic component and a wire harness of the vehicle.

9. The vehicular interior rearview mirror assembly of claim 8, wherein a separator is within the passageway to separate the airflow through the passageway and the electrical connector.

10. The vehicular interior rearview mirror assembly of claim 1, wherein the socket is thermally coupled to the heatsink, and wherein the socket draws heat away from the heatsink, and wherein the ball member is thermally coupled to the socket, and wherein the arm and the ball member draw heat away from the socket.

11. The vehicular interior rearview mirror assembly of claim 1, wherein the mirror head accommodates a driver monitoring camera that captures image data for a driver monitoring function.

12. The vehicular interior rearview mirror assembly of claim 11, wherein the electronic component comprises the driver monitoring camera.

13. The vehicular interior rearview mirror assembly of claim 11, wherein the mirror head accommodates a printed circuit board (PCB) comprising an image processor for processing image data captured by the driver monitoring camera, and wherein the electronic component comprises the image processor.

14. The vehicular interior rearview mirror assembly of claim 1, wherein the mirror head accommodates a video display screen, and wherein the video display screen, when electrically operated, displays video images that are viewable by a driver of the vehicle, and wherein the electronic component comprises the video display screen.

15. A vehicular interior rearview mirror assembly, the vehicular interior rearview mirror assembly comprising:
a mirror head adjustable about a mounting structure, wherein the mounting structure is configured to mount the vehicular interior rearview mirror assembly at an interior portion of an interior cabin of a vehicle;
wherein the mounting structure includes an arm having a ball member;
wherein the mirror head comprises one or more vents formed through an outer surface of the mirror head;
wherein the mirror head comprises a mirror reflective element and a socket, and wherein the socket receives the ball member to adjustably mount the mirror head at the mounting structure;
wherein the arm and the ball member have a passageway;
wherein the mirror head accommodates a driver monitoring camera that captures image data for a driver monitoring function;
wherein the mirror head accommodates a printed circuit board (PCB) within an interior cavity of the mirror head, and wherein the PCB comprises an image processor for processing image data captured by the driver monitoring camera;
a heatsink accommodated by the mirror head, wherein the heatsink is thermally coupled to the PCB and the image processor;
wherein, when the image processor is electrically operated and generates heat within the interior cavity of the mirror head, the heatsink draws heat away from the PCB and the image processor; and
wherein, with the vehicular interior rearview mirror assembly mounted at the interior portion of the interior cabin of the vehicle, an air source directs airflow through the passageway of the arm and the ball member and into the interior cavity of the mirror head, and wherein the airflow flows through the interior cavity of the mirror head and exits the interior cavity of the mirror head through the one or more vents to dissipate heat from the heatsink and the interior cavity of the mirror head.

16. The vehicular interior rearview mirror assembly of claim 15, wherein the ball member is disposed at a first end of the arm, and wherein the passageway has a first opening at the ball member and a second opening at a second end of the arm opposite the first end.

17. The vehicular interior rearview mirror assembly of claim 16, wherein the air source comprises a fan assembly disposed at the second end of the arm, and wherein the fan assembly comprises an electrically operable fan that, when electrically operated, directs the airflow toward the second opening of the passageway.

18. The vehicular interior rearview mirror assembly of claim 17, wherein the electrically operable fan comprises a radial fan that directs air in a radial direction relative to an axis of rotation of the electrically operable fan.

19. A vehicular interior rearview mirror assembly, the vehicular interior rearview mirror assembly comprising:
a mirror head adjustable about a mounting structure, wherein the mounting structure is configured to mount the vehicular interior rearview mirror assembly at an interior portion of an interior cabin of a vehicle;
wherein the mounting structure includes an arm having a ball member;
wherein the mirror head comprises one or more vents formed through an outer surface of the mirror head;
wherein the mirror head comprises a mirror reflective element and a socket, and wherein the socket receives the ball member to adjustably mount the mirror head at the mounting structure;
wherein the arm and the ball member have a passageway;
wherein the mirror head accommodates a video display screen within an interior cavity of the mirror head, and wherein the video display screen, when electrically operated, displays video images that are viewable by a driver of the vehicle;
wherein, with the vehicular interior rearview mirror assembly mounted at the interior portion of the interior cabin of the vehicle, an electrical connector passes through the passageway to electrically connect the video display screen and a wire harness of the vehicle;
a heatsink accommodated by the mirror head, wherein the heatsink is thermally coupled to the video display screen;
wherein, when the video display screen is electrically operated and generates heat within the interior cavity of the mirror head, the heatsink draws heat away from the video display screen; and
wherein, with the vehicular interior rearview mirror assembly mounted at the interior portion of the interior cabin of the vehicle, an air source directs airflow through the passageway of the arm and the ball member and into the interior cavity of the mirror head, and wherein the airflow flows through the interior cavity of the mirror head and exits the interior cavity of the mirror head through the one or more vents to dissipate heat from the heatsink and the interior cavity of the mirror head.

20. The vehicular interior rearview mirror assembly of claim 19, wherein the ball member is disposed at a first end of the arm, and wherein the passageway has a first opening at the ball member and a second opening at a second end of the arm opposite the first end.

21. The vehicular interior rearview mirror assembly of claim 20, wherein the air source comprises a fan assembly disposed at the second end of the arm, and wherein the fan assembly comprises an electrically operable fan that, when electrically operated, directs the airflow toward the second opening of the passageway.

22. The vehicular interior rearview mirror assembly of claim 21, wherein the electrically operable fan comprises a radial fan that directs air in a radial direction relative to an axis of rotation of the electrically operable fan.

23. The vehicular interior rearview mirror assembly of claim 19, wherein a separator is within the passageway to separate the airflow through the passageway and the electrical connector.
